(19) United States
(12) Patent Application Publication
(10) Pub. No.: US 2026/0310535 A1
(43) Pub. Date: Oct. 8, 2026

(54) OPTIMIZING DECODER UTILIZATION USING FAILED BIT COUNT PREDICTION-BASED ROUTING

(71) Applicant: Sandisk Technologies, Inc., Milpitas, CA (US)

(72) Inventors: Eran Sharon, Rishon Lezion (IL); Alexander Bazarsky, Amsterdam (NL); David Avraham, Even Yehuda (IL); Ariel Navon, Revava (IL)

(21) Appl. No.: 19/169,136

(22) Filed: Apr. 3, 2025

(51) Int. Cl. G06F 11/07

(52) U.S. Cl. CPC G06F 11/076; G06F 11/0709

(57) ABSTRACT

A data storage device includes a decoder selection system that determines one or more properties associated with data identified by a read command. The decoder selection system provides the one or more properties to a model that predicts a failed bit count of the data without reading the data. Based on the predicted failed bit count, the decoder selection system identifies a particular decoder from a pool of decoders and routes a codeword associated with the data to the particular decoder.

### BACKGROUND

When data is written to a data storage device, such as a NAND data storage device, the data is associated with additional redundant bits, or error correction code (ECC) bits. The data and the ECC bits are used to generate a codeword that is stored in the data storage device. During a read operation, the codeword and the associated data is retrieved and read to determine whether the codeword and/or the data include errors. If errors are detected, a decoder is used to correct the errors.

Some data storage devices utilize a number of different decoders and each decoder has different error correction capabilities, power consumption profiles, latencies and speeds. For example, an ultra-low power (ULP) decoder is typically faster, in terms of decoding time, when compared to a Low Power (LP) decoder and a Full Power (FP) decoder. However, the correction capabilities of the ULP decoder are more limited when compared to the correction capabilities of the LP decoder and the FP decoder.

In examples in which the data storage device uses different decoders, one or more codewords are sent to the different decoders based, at least in part, by determining a syndrome weight, or a bit error rate (BER), of the codeword. If the codeword has a first BER, the codeword is sent to the ULP decoder. However, if the codeword has a second BER, the codeword is sent to the LP decoder or the FP decoder. Each time the codeword is routed to a particular decoder, the data and/or the codeword must undergo a read operation and/or an analysis operation to determine the BER of the codeword. Each read and/or analysis operation increases latency and decreases throughput which negatively impacts the performance of the data storage device.

Accordingly, it would be beneficial to improve a decoder selection process for data storage devices having multiple different decoders.

Examples of the present disclosure describe a data storage device, such as, for example, a NAND data storage device, that includes a decoder selection system. The decoder selection system, along with a property determination system and a failed bit count (FBC) prediction system, determine one or more properties or characteristics associated with data and/or a codeword. The decoder selection system routes the codeword to a particular decoder based on the one or more properties or characteristics. In an example, the decoder selection system routes the codeword to the particular decoder without reading and/or analyzing the data or the codeword and/or determining a bit error rate (BER) or syndrome weight of the codeword.

Accordingly, examples of the present disclosure describe a method that includes receiving a command from a host device. In an example, the command identifies data to be read from a data storage device. The method also includes identifying one or more properties associated with the data and predicting based, at least in part, on the one or more properties associated with the data, a failed bit count (FBC) of the data while bypassing a read operation that determines a bit error rate (BER) of one or more codewords associated with the data. When the FBC of the data is determined, a particular decoder from a pool of decoders is identified. In an example, the particular decoder is identified based, at least in part, on the FBC of the data. The one or more codewords associated with the data is then provided to the particular decoder.

Other examples describe a controller for a data storage device. In an example, the controller includes a property determination system operable to determine one or more properties associated with data identified in a read request received from a host device. The controller also includes a failed bit count (FBC) prediction system operable to predict a FBC of the data while bypassing a read operation that determines a bit error rate (BER) of one or more codewords associated with the data. The controller also includes a decoder selection system operable to select a particular decoder from a pool of decoders that will decode the one or more codewords associated with the data. In an example, the decoder selection system selects the particular decoder based, at least in part, on the FBC of the data.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a block diagram of a system that includes a host device and a data storage device according to an example.

FIG. 2 illustrates a pool of decoders having a number of different decoder gears according to an example.

FIG. 3 illustrates a graph that shows how different properties of data affect a predicted FBC of the data according to an example.

FIG. 4 illustrates how a model is used to determine a FBC of data according to an example.

FIG. 5 illustrates a method for predicting a FBC of data and for selecting a particular decoder based on the predicted FBC according to an example.

FIG. 6 is a perspective view of a storage device that includes three-dimensional (3D) stacked non-volatile memory according to an example.

FIG. 7 is a block diagram of a storage device according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Some data storage devices, such as, for example, NAND data storage devices, utilize a number of different decoders during an error correction code (ECC) process. Each decoder has different error correction capabilities, power consumption profiles, latency profiles and speeds. For example, a first tier decoder, or an Ultra-Low Power (ULP) decoder, is typically faster when compared to a second tier decoder, or a Low Power (LP) decoder and/or a third tier decoder, or a Full Power (FP) decoder.

During a codeword decoding process, a codeword is read and/or analyzed to determine a syndrome weight or a bit error rate (BER). The codeword is then routed to a particular decoder based on the determined BER. For example, if the codeword has a first BER, the codeword is sent to the ULP decoder. However, if the codeword has a second BER, the codeword is sent to the LP decoder or the FP decoder. However, as previously explained, each read and/or analysis operation increases latency and decreases throughput, which negatively impacts the performance of the data storage device

To address the above, examples of the present disclosure describe a decoder selection system for a data storage device. In an example, the decoder selection system is associated with a controller of the data storage device. In some examples, the data storage device is a NAND data storage device. The controller also includes a property determination system and a failed bit count (FBC) prediction system. Each of these systems work in conjunction with each other to determine one or more properties or characteristics associated with the data and/or codeword. The decoder selection system routes the codeword to a particular decoder based, at least in part, on the one or more properties or characteristics. In an example, the decoder selection system routes the codeword to the particular decoder without reading and/or analyzing the data or the codeword and/or determining a bit error rate (BER) or syndrome weight of the codeword. In addition to identifying and selecting a particular decoder, the decoder selection system also identifies and/or selects a parallelism level of the decoder.

In accordance with the above, many technical benefits may be realized including, but not limited to increasing the QoS and throughput of a data storage device and reducing latency of the data storage device thereby increasing the reliability and performance of the data storage device.

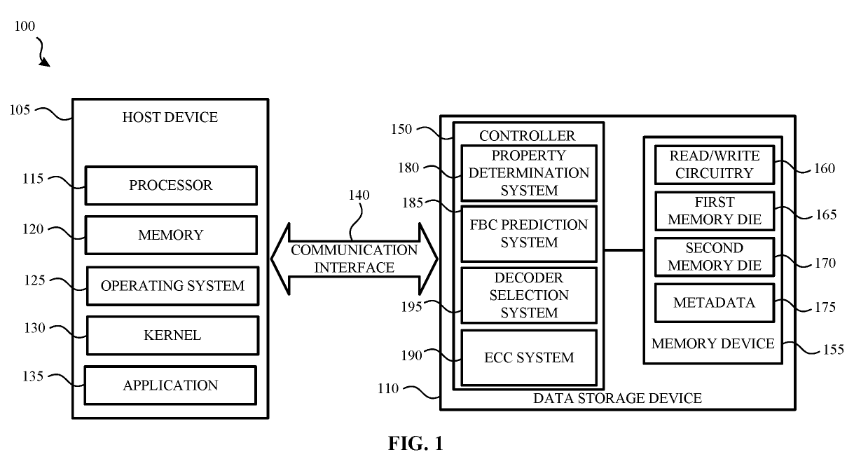

These benefits, along with other examples, will be shown and described in greater detail with respect to FIGS. 1 - 7.

FIG. 1 is a block diagram of a system 100 that includes a host device 105 and a data storage device 110 according to an example. In an example, the host device 105 includes a processor 115 and a memory 120 (e.g., main memory). The memory 120 may include or otherwise be associated with an operating system 125, a kernel 130 and/or an application 135.

The processor 115 can execute various instructions, such as, for example, instructions from the operating system 125 and/or the application 135. The processor 115 includes circuitry such as a microcontroller, a Digital Signal Processor (DSP), an Application-Specific Integrated Circuit (ASIC), a Field Programmable Gate Array (FPGA), hard-wired logic, analog circuitry and/or various combinations thereof. In an example, the processor 115 includes a System on a Chip (SoC).

In an example, the memory 120 is used by the host device 105 to store data that is used, or otherwise executed by, the processor 115. Data stored in the memory 120 includes instructions provided by the data storage device 110 via a communication interface 140. The data stored in the memory 120 also includes data used to execute instructions from the operating system 125 and/or one or more applications 135. In an example, the memory 120 is a single memory. In another example, the memory 120 includes multiple memories, such as, for example, one or more non-volatile memories, one or more volatile memories, or a combination thereof.

In an example, the operating system 125 creates a virtual address space for the application 135 and/or other processes executed by the processor 115. The virtual address space maps to locations in the memory 120. The operating system 125 also includes, or is otherwise associated with, a kernel 130. In an example, the kernel 130 includes instructions for managing various resources of the host device 105 (e.g., memory allocation), handling read and write requests and performing other operations.

The communication interface 140 communicatively couples the host device 105 and the data storage device 110. The communication interface 140 may be a Serial Advanced Technology Attachment (SATA), a PCI express (PCIe) bus, a Small Computer System Interface (SCSI), a Serial Attached SCSI (SAS), Ethernet, Fibre Channel, or Wi-Fi. As such, the host device 105 and the data storage device 110 need not be physically co-located and may communicate over a network such as a Local Area Network (LAN) or a Wide Area Network (WAN), such as the internet. In addition, the host device 105 interfaces with the data storage device 110 using a logical interface specification such as Non-Volatile Memory express (NVMe) or Advanced Host Controller Interface (AHCI).

The data storage device 110 also includes a controller 150 and a memory device 155. In an example, the controller 150 is communicatively coupled to the memory device 155. The memory device 155 includes one or more memory dies (e.g., first memory die 165 and second memory die 170). Although memory dies are specifically mentioned, the memory device 155 may include any non-volatile memory device, storage device, storage elements or storage medium including NAND flash memory cells and/or NOR flash memory cells.

The memory cells can take the form of solid-state (e.g., flash) memory cells and can be one-time programmable, few-time programmable, or many-time programmable. Additionally, the memory cells may be single-level cells (SLCs), multi-level cells (MLCs), triple-level cells (TLCs), quad-level cells (QLCs), penta-level cells (PLCs), and/or use any other memory technologies. The memory cells are arranged in a two-dimensional configuration or a three-dimensional configuration.

In some examples, the data storage device 110 is attached to or embedded within the host device 105. In another example, the data storage device 110 is implemented as an external device or a portable device that can be communicatively or selectively coupled to the host device 105. In yet another example, the data storage device 110 is a component (e.g., a solid-state drive (SSD)) of a network accessible data storage system, a network-attached storage system, a cloud data storage system, and the like.

As indicated above, the memory device 155 of the data storage device 110 includes a first memory die 165 and a second memory die 170. Although two memory dies are shown, the memory device 155 may include any number of memory dies (e.g., one memory die, two memory dies, eight memory dies, or another number of memory dies).

The memory device 155 also includes support circuitry. In an example, the support circuitry includes read/write circuitry 160. The read/write circuitry 160 supports the operation of the memory dies of the memory device 155. Although the read/write circuitry 160 is depicted as a single component, the read/write circuitry 160 may be divided into separate components, such as, for example, read circuitry and write circuitry. The read/write circuitry 160 may be external to the memory dies of the memory device 155. In another example, one or more of the memory dies include corresponding read/write circuitry 160 that is operable to read data from and/or write data to storage elements within one individual memory die independent of other read and/or write operations on any of the other memory dies.

In an example, one or more of the first memory die 165 and the second memory die 170 include one or more memory blocks. In an example, each memory block includes one or more memory cells. A block of memory cells is the smallest number of memory cells that are physically erasable together. In an example and for increased parallelism, each of the blocks may be operated or organized in larger blocks or metablocks. For example, one block from different planes of memory cells may be logically linked together to form a metablock.

As previously described, the data storage device 110 also includes at least one controller 150. Although a single controller 150 is shown and described, the data storage device 110 can include multiple controllers. In such example, a first controller performs a first operation or set of operations and a second controller performs a second operation or set of operations. The operations may be performed in parallel, substantially in parallel or in sequence.

The controller 150 is communicatively coupled to the memory device 155 via a bus, an interface or other communication circuitry. In an example, the communication circuitry includes one or more channels which enable the controller 150 to communicate with the first memory die 165 and/or the second memory die 170 of the memory device 155. In another example, the communication circuitry includes multiple distinct channels which enables the controller 150 to communicate with the first memory die 165 independently and/or in parallel with the second memory die 170 of the memory device 155.

The controller 150 receives data and/or instructions from the host device 105. The controller 150 may also send data to the host device 105. For example, the controller 150 may send data to and/or receive data from the host device 105 via the communication interface 140.

The controller 150 may also send data and/or commands to and/or receive data from the memory device 155. For example, the controller 150 sends data and a corresponding write command to the memory device 155 to cause the memory device 155 to store data at a specified address of the memory device 155. In an example, the write command specifies a physical address of a portion of the memory device 155.

The controller 150 also sends data and/or commands associated with one or more background scanning operations, garbage collection operations, and/or wear leveling operations. The controller 150 may also send one or more read commands to the memory device 155. In an example, the read command specifies the physical address of a portion of the memory device 155 at which the data is stored.

The controller 150 also includes or is otherwise associated with an error correction code (ECC) system 190. The ECC system 190 receives data and generates one or more ECC codewords based, at least in part, on the received data. For example, the ECC system 190 includes at least one encoder that encodes the received data using one or more encoding techniques.

The ECC system 190 also includes at least one decoder that decodes data read from the memory device 155. In an example, the ECC system 190 includes multiple decoders. Some of the decoders are of a first type and have a first amount of error correction capabilities, speed, power requirements and/or latency profile while some of the decoders are of a second type and/or a third type that have second/third amount of error correction capabilities, speeds, power requirements and/or latency profiles.

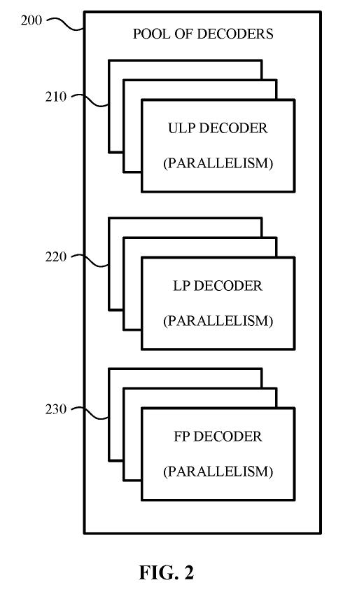

For example and referring to FIG. 2, FIG. 2 illustrates a pool of decoders 200 having a number of different decoder gears according to an example. In addition to having different decoder gears, each decoder may have, or otherwise be associated with, a different parallelism level and/or have a number of different decoding cores.

In an example, the pool of decoders 200 includes one or more Ultra-Low Power (ULP) decoders 210, one or more Low Power (LP) decoders 220 and one or more Full Power (FP) decoders 230. In an example, the ULP decoder is a bit-flipping decoder and the LP decoder and the FP decoders are belief propagation (BP) decoders. In an example, the ULP decoder is more power and cost efficient (in the relative bit error rate (BER) range) when compared with the LP decoder and the FP decoder. Additionally, the ULP decoder can be used with higher parallelism or a higher clock frequency when compared with the LP decoder and FP decoder. Thus, the ULP decoder allows for higher decoding throughput while keeping the power consumption relatively constant when compared with the LP decoder and the FP decoder. However, as previously described, the ULP decoder has limited correction capabilities when compared with the with the LP decoder and the FP decoder.

In an example, the pool of decoders 200 may have any number of decoders, each with the same or different parallelism rates. For example, the pool of decoders 200 may have 128 ULP decoders 210, 16 LP decoders 220 and 4 FP decoders 230. In an example, 8 of the LP decoders 220 are built with a low parallelism rate and 8 of the LP decoders 220 have a high parallelism rate. Although specific numbers are given, these are for example purposes only.

In current solutions, when a codeword is decoded, an ECC system is required to read the data associated with the codeword and/or read the codeword, determine a BER and/or a syndrome weight of the codeword and select the appropriate decoder based on the BER. In contrast, and referring back to FIG. 1, the data storage device 110 and/or the controller 150 of the present disclosure includes systems and/or circuitry to predict or determine a failed bit count (FBC) of data or a codeword associated with the data based, at least in part, on one or more properties or characteristics of the data and/or the codeword and without first reading the data and/or the codeword. Based, at least in part, on the prediction of the FBC, the codeword is routed to a particular decoder and/or to a particular decoder having a particular parallelism rate and/or a number of decoding cores.

For example, in addition to the ECC system 190, the controller 150 includes, or is otherwise associated with, a property determination system 180, a FBC prediction system 185, and a decoder selection system 195. The property determination system 180, the FBC prediction system 185 and/or the decoder selection system 195 may also be part of the ECC system 190. In other examples, the property determination system 180, the FBC prediction system 185 and/or the decoder selection system 195 are separate from the ECC system 190.

Additionally, one or more of the property determination system 180, the FBC prediction system 185, the decoder selection system 195 and/or the ECC system may be packaged functional hardware units designed for use with other components/systems, a portion of a program code (e.g., software or firmware) executable by the controller 150, a processor and/or processing circuitry, or a self-contained hardware and/or software component that interfaces with other components and/or systems.

In an example, when a command, such as a read command, is received from the host device 105, the controller 150 identifies the data associated with the received command. The property determination system 180 is operable to determine one or more properties or characteristics associated with the data. As will be explained in greater detail herein, the one or more properties or characteristics are used to determine a FBC of the data identified by the command. In an example, the one or more properties are physical properties, such as a physical location at which the data is stored. In another example, the one or more properties are based on other factors.

In an example, the one or more properties associated with the data include, but are not limited to, a cross-temperature associated with the data (e.g., temperature of a memory die and/or the memory device 155 when the data is written versus when the data is read); a number of program erase (P/E) cycles associated with the data; a wordline number and/or a wordline zone at which the data is stored (e.g., data stored on edge wordlines is more susceptible to errors when compared with data stored on other wordlines); a time-pool grade associated with the data (e.g., an amount of time that has elapsed since the data was programmed and/or refreshed); a read/disturb counter associated with the data; a default offset read level of a memory block on which the data is stored (e.g., a measure of one or more read voltage levels for the memory block); a page type associated with the data (e.g., whether the data is stored on an upper page; a middle page or a lower page); a string number associated with the data; a plane of a memory die (e.g., a plane number) on which the data is stored; a total erase count associated with the memory block and/or memory die on which the data is stored; and a data retention select value (e.g., higher data retention is more prone to errors). In some examples, some, or all of this data is stored by the memory device 155 as metadata 175. Although a number of different properties and characteristics are mentioned, the property determination system 180 may identify one, some, or all of the properties when the command is received and/or the data is identified.

In some examples, the various properties are weighted or ranked with respect to one another. For example, one property or characteristic may be a better indication of a FBC when compared with another property or characteristic. For example, a page type on which the data is stored and/or a wordline number associated with the data may provide better predictors when compared to the timepool offset.

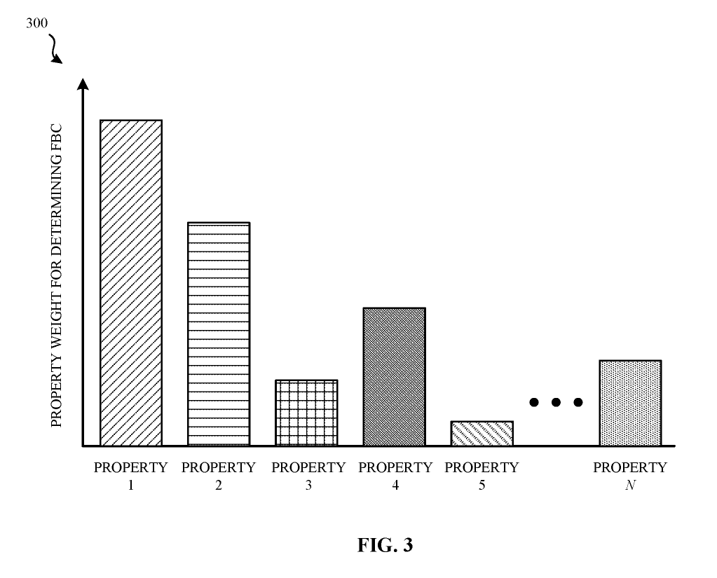

FIG. 3 illustrates a graph 300 that shows how different properties of data affect a predicted FBC of the data according to an example. For example, a property determination system, such as the property determination system 180 (FIG. 1), may track or identify N properties associated with the data. In this example, Property 1 may have the greatest impact on the FBC prediction, followed by Property 2 and Property 4. Property N has less impact, followed by Property 3 and Property 5.

Referring back to FIG. 1, when one or more properties of the data are identified, the property determination system 180 provides the identified or determined information to the FBC prediction system 185. The FBC prediction system 185 uses the information to predict a FBC of the data associated with the received command.

In one example, the FBC prediction system 185 uses a model to predict the FBC of the data. For example, the FBC prediction system 185 uses a statistical model (e.g., a tree model, a neural network), that was trained in an offline environment, to predict the FBC of the data based, at least in part, on the one or more properties identified or determined by the property determination system 180.

For example, the FBC prediction system 185 inputs the information determined by the property determination system 180 into the model. The model then provides a predicted FBC of the data based on the information. In an example, model determines or predicts a maximal duration of allocation time of various decoding resources. When the FBC of the data has been predicted, the decoder selection system 195 selects a decoder and/or a parallelism rate, that will be used to decode one or more codeword associated with the data. The decoder selection system 195 then provides one or more codewords associated with the data to the selected and/or identified decoder.

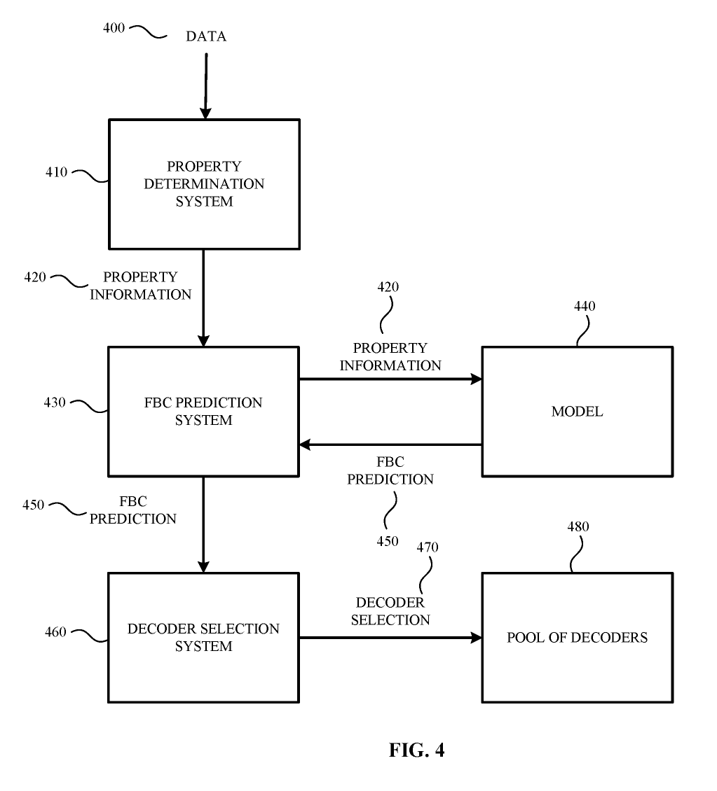

For example, and referring to FIG. 4, FIG. 4 illustrates how a model 440 is used to determine a FBC of data 400 according to an example. In an example, the various systems shown and described with respect to FIG. 4 are similar to the various system shown and described with respect to FIG. 1. For example, the property determination system 410 is similar to the property determination system 180 of FIG. 1. Likewise, the FBC prediction system 430 is similar to the FBC prediction system 185 of FIG. 1 and the decoder selection system 460 is similar to the decoder selection system 195 of FIG. 1.

As shown in FIG. 4 when data 400 associated with a command is identified, the property determination system 410 analyzes the data 400 to determine property information 420 of the data. As previously explained, the property information 420 may be physical properties of the data such as, for example, information corresponding to a wordline or page on which the data is stored. In another example, the property information may include other information such as cross-temperature information, time-pool offset information and the like.

When the property determination system 410 determines or identifies the property information, the property information 420 is provided to the FBC prediction system 430. The FBC prediction system 430 provides the property information 420 to a model 440. Although the model 440 is shown as being separate from the FBC prediction system 430, the model 440 may be part of the FBC prediction system 430. In addition, the FBC prediction system 430 can update the model 440 based on feedback received from one or more decoding operations. For example, when a decoder or decoder gear is ultimately selected, the decoder selection system 460 can provide feedback or other information about whether the predicted FBC was accurate. The FBC prediction system 430 can then update the model (e.g., update the weight of one or more properties that are used to determine the FBC) using the feedback.

When the model 440 has received property information 420, the model 440 uses the property information to provide a FBC prediction 450. The FBC prediction system 430 provides the FBC prediction 450 to the decoder selection system 460. The decoder selection system 460 uses the FBC prediction 450 to identify or select a particular decoder (e.g., decoder selection 470), and/or a decoder with a particular parallelism rate (or a decoder with a particular number of decoding cores), from a pool of decoders 480. In an example, the pool of decoders 480 is similar to the pool of decoders 200 show and described with respect to FIG. 2.

When a particular decoder is selected or identified, a codeword associated with the data 400 is provided to the selected decoder, thereby bypassing any read operations on the data 400 and/or on the codeword.

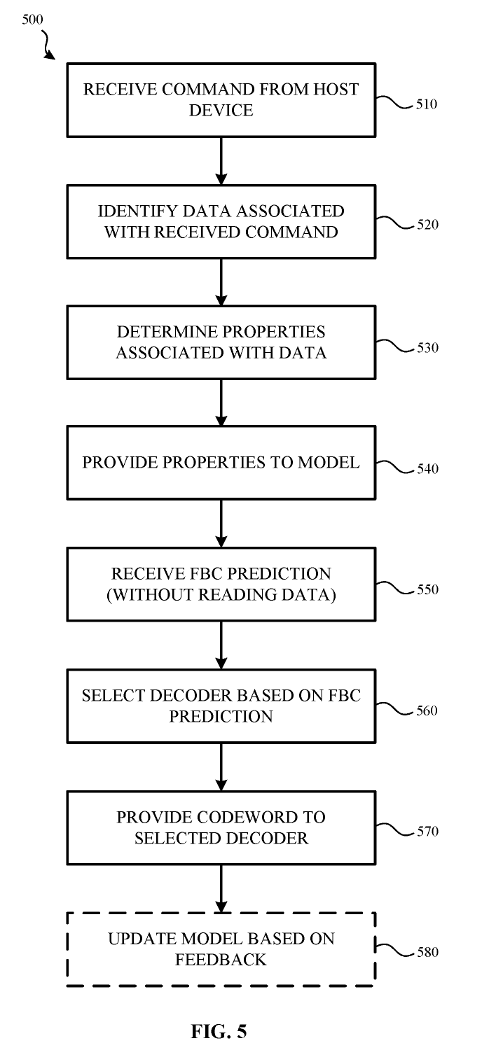

FIG. 5 illustrates a method 500 for predicting a FBC of data and for selecting a particular decoder based on the predicted FBC according to an example. In an example, the method 500 is performed by controller and/or various systems, firmware and/or hardware associated with the controller such as for example, the controller 150 shown and described with respect to FIG. 1.

In an example, the method 500 begins when a command is received (510) from a host device. In an example, the command is a read command that identifies data that is to be read from a data storage device.

When the command is received, the controller identifies (520) data associated with the command. As part of this operation, the controller also determines (530) one or more properties associated with the data such as previously described.

In response to determining the properties, the determined properties are provided to a model. In an example, the model is a statistical model that has been trained in an offline environment. For example, the model has been trained with FBCs, BERs and/or syndrome weights of data based on the data for the model being read and cross-referenced with the various properties previously discussed.

In response to receiving the determined properties, the model provides a FBC prediction which is received (550) by the controller. The controller then selects (560) a particular decoder from a pool of decoders based, at least in part, on the FBC prediction. In an example, the decoder, and a parallelism rate of the decoder, is selected using only the FBC prediction, and the data or the codeword is not read or otherwise analyzed.

When the decoder has been identified or selected, the controller provides (570) one or more codewords associated with the data to the selected decoder. The controller also (optionally) captures feedback from one or more decoding processes and/or updates (580) the model based on the feedback.

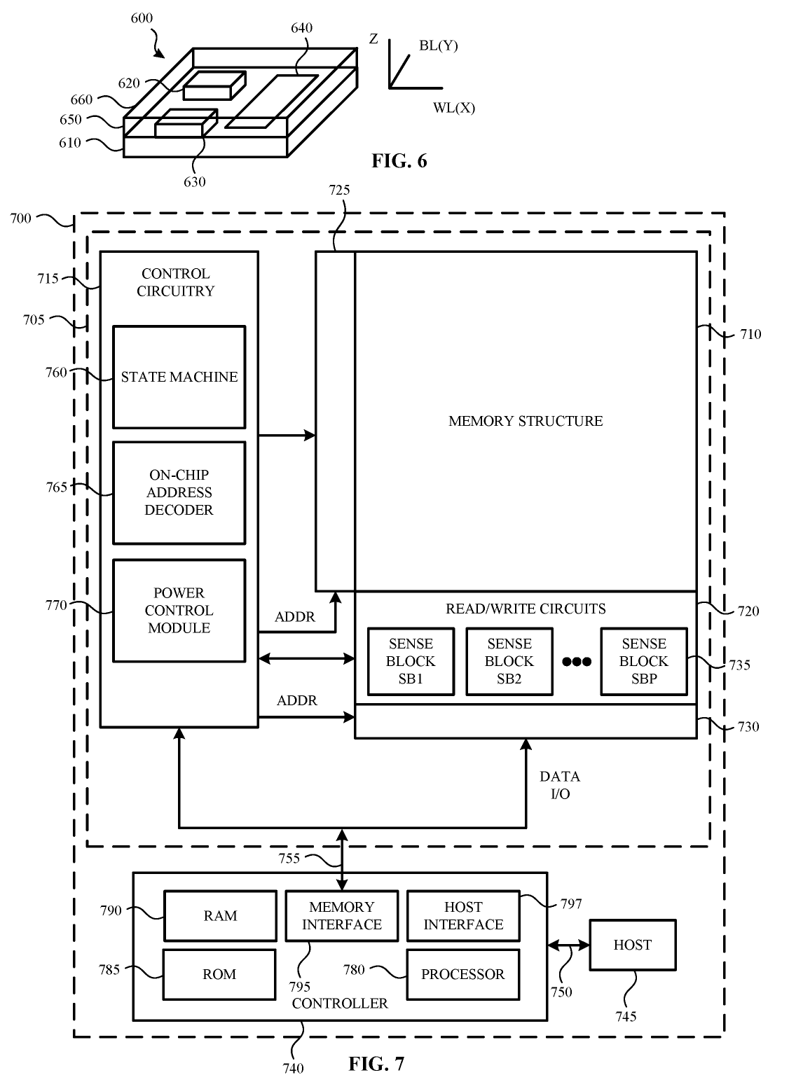

FIGS. 6 - 7 describe example storage devices that may be used with or otherwise implement the various features described herein. For example, the storage devices shown and described with respect to FIGS. 6 - 7 may include various systems and components that are similar to the systems and components shown and described with respect to FIG. 1. For example, the controller 740 shown and described with respect to FIG. 7 may be similar to the controller 150 of FIG. 1. Likewise, the memory dies 705 may be similar to the first memory die 165 and/or the second memory die 170 of FIG. 1.

FIG. 6 is a perspective view of a storage device 600 that includes three-dimensional (3D) stacked non-volatile memory according to an example. In this example, the storage device 600 includes a substrate 610. Blocks of memory cells are included on or above the substrate 610. The blocks may include a first block (BLK0620) and a second block (BLK1630). Each block may be formed of memory cells (e.g., non-volatile memory elements). The substrate 610 may also include a peripheral area 640 having support circuits that are used by the first block and the second block.

The substrate 610 may also carry circuits under the blocks, along with one or more lower metal layers which are patterned in conductive paths to carry signals from the circuits. The blocks may be formed in an intermediate region 650 of the storage device 600. The storage device may also include an upper region 660. The upper region 660 may include one or more upper metal layers that are patterned in conductive paths to carry signals from the circuits. Each block of memory cells may include a stacked area of memory cells. In an example, alternating levels of the stack represent word lines. While two blocks are depicted, additional blocks may be used and extend in the x-direction and/or the y-direction.

In an example, a length of a plane of the substrate 610 in the x-direction represents a direction in which signal paths for word lines or control gate lines extend (e.g., a word line or drain-end select gate (SGD) line direction) and the width of the plane of the substrate 610 in the y-direction represents a direction in which signal paths for bit lines extend (e.g., a bit line direction). The z-direction represents a height of the storage device 600.

FIG. 7 is a functional block diagram of a storage device 700 according to an example. In an example, the storage device 700 is the 3D stacked non-volatile storage device 600 shown and described with respect to FIG. 6. The components depicted in FIG. 7 may be electrical circuits. In an example, the storage device 700 includes one or more memory dies 705. Each memory die 705 includes a three-dimensional memory structure 710 of memory cells (e.g., a 3D array of memory cells), control circuitry 715, and read/write circuits 720. In another example, a two-dimensional array of memory cells may be used. The memory structure 710 is addressable by word lines using a first decoder 725 (e.g., a row decoder) and by bit lines using a second decoder 730 (e.g., a column decoder). The read/write circuits 720 may also include multiple sense blocks 735 including SB1, SB2, . . ., SBp (e.g., sensing circuitry) which allow pages of the memory cells to be read or programmed in parallel. The sense blocks 735 may include bit line drivers.

In an example, a controller 740 is included in the same storage device 700 as the one or more memory dies 705. In another example, the controller 740 is formed on a die that is bonded to a memory die 705, in which case each memory die 705 may have its own controller 740. In yet another example, a controller die controls all of the memory dies 705.

Commands and data may be transferred between a host 745 and the controller 740 using a data bus 750. Commands and data may also be transferred between the controller 740 and one or more of the memory dies 705 by way of lines 755. In one example, the memory die 705 includes a set of input and/or output (I/O) pins that connect to lines 755.

The memory structure 710 may also include one or more arrays of memory cells. The memory cells may be arranged in a three-dimensional array or a two-dimensional array. The memory structure 710 may include any type of non-volatile memory that is formed on one or more physical levels of arrays of memory cells having an active area disposed above a silicon substrate. The memory structure 710 may be in a non-volatile memory device having circuitry associated with the operation of the memory cells, whether the associated circuitry is above or within the substrate.

The control circuitry 715 works in conjunction with the read/write circuits 720 to perform memory operations (e.g., erase, program, read, and others) on the memory structure 710. The control circuitry 715 may include registers, ROM fuses, and other devices for storing default values such as base voltages and other parameters.

The control circuitry 715 may also include a state machine 760, an on-chip address decoder 765 and a power control module 770. The state machine 760 may provide chip-level control of various memory operations. The state machine 760 may be programmable by software. In another example, the state machine 760 does not use software and is completely implemented in hardware (e.g., electrical circuits). The on-chip address decoder 765 may provide an address interface between addresses used by host 745 and/or the controller 740 to a hardware address used by the first decoder 725 and the second decoder 730.

The power control module 770 may control power and voltages that are supplied to the word lines and bit lines during memory operations. The power control module 770 may include drivers for word line layers in a 3D configuration, select transistors (e.g., SGS and SGD transistors) and source lines. The power control module 770 may include one or more charge pumps for creating voltages.

The control circuitry 715, the state machine 760, the on-chip address decoder 765, the first decoder 725, the second decoder 730, the power control module 770, the sense blocks 735, the read/write circuits 720, and/or the controller 740 may be considered one or more control circuits and/or a managing circuit that perform some or all of the operations described herein.

In an example, the controller 740, is an electrical circuit that may be on-chip or off-chip. Additionally, the controller 740 may include one or more processors 780, ROM 785, RAM 790, memory interface 795, and host interface 797, all of which may be interconnected. In an example, the one or more processors 780 is one example of a control circuit. Other examples can use state machines or other custom circuits designed to perform one or more functions. Devices such as ROM 785 and RAM 790 may include code such as a set of instructions. One or more of the processors 780 may be operable to execute the set of instructions to provide some or all of the functionality described herein.

Alternatively or additionally, one or more of the processors 780 may access code from a memory device in the memory structure 710, such as a reserved area of memory cells connected to one or more word lines. The memory interface 795, in communication with ROM 785, RAM 790, and one or more of the processors 780, may be an electrical circuit that provides an electrical interface between the controller 740 and the memory die 705. For example, the memory interface 795 may change the format or timing of signals, provide a buffer, isolate from surges, latch I/O, and so forth.

The one or more processors 780 may issue commands to control circuitry 715, or any other component of memory die 705, using the memory interface 795. The host interface 797, in communication with the ROM 785, the RAM 790, and the one or more processors 780, may be an electrical circuit that provides an electrical interface between the controller 740 and the host 745. For example, the host interface 797 may change the format or timing of signals, provide a buffer, isolate from surges, latch I/O, and so on. Commands and data from the host 745 are received by the controller 740 by way of the host interface 797. Data sent to the host 745 may be transmitted using the data bus 750.

Multiple memory elements in the memory structure 710 may be configured so that they are connected in series or so that each element is individually accessible. By way of a non-limiting example, flash memory devices in a NAND configuration (e.g., NAND flash memory) typically contain memory elements connected in series. A NAND string is an example of a set of series-connected memory cells and select gate transistors.

A NAND flash memory array may also be configured so that the array includes multiple NAND strings. In an example, a NAND string includes multiple memory cells sharing a single bit line and are accessed as a group. Alternatively, memory elements may be configured so that each memory element is individually accessible (e.g., a NOR memory array). The NAND and NOR memory configurations are examples and memory cells may have other configurations.

The memory cells may be arranged in the single memory device level in an ordered array, such as in a plurality of rows and/or columns. However, the memory elements may be arrayed in non-regular or non-orthogonal configurations, or in structures not considered arrays.

In an example, a 3D memory structure may be vertically arranged as a stack of multiple 2D memory device levels. As another non-limiting example, a 3D memory array may be arranged as multiple vertical columns (e.g., columns extending substantially perpendicular to the major surface of the substrate, such as in the y direction) with each column having multiple memory cells. The vertical columns may be arranged in a two-dimensional arrangement of memory cells, with memory cells on multiple vertically stacked memory planes. Other configurations of memory elements in three dimensions can also constitute a 3D memory array.

In another example, in a 3D NAND memory array, the memory elements may be coupled together to form vertical NAND strings that traverse across multiple horizontal memory device levels. Other 3D configurations can be envisioned wherein some NAND strings contain memory elements in a single memory level while other strings contain memory elements which span through multiple memory levels. 3D memory arrays may also be designed in a NOR configuration and in a ReRAM configuration.

Accordingly, examples of the present disclosure describe a method, comprising: receiving a command from a host device, the command denoting data to be read from a data storage device; identifying one or more properties associated with the data; predicting based, at least in part, on the one or more properties associated with the data, a failed bit count (FBC) of the data while bypassing a read operation that determines a bit error rate (BER) of one or more codewords associated with the data; identifying a particular decoder from a pool of decoders based, at least in part, on the FBC of the data; and providing the one or more codewords associated with the data to the particular decoder. In an example, the method also includes determining based, at least in part, on the FBC associated with the data, a parallelism rate for the particular decoder. In an example, the one or more properties are physical properties of one or more memory blocks in which the data is stored. In an example, the one or more properties are provided to a model that predicts the FBC of the data. In an example, the model is trained in an offline environment. In an example, the method also includes updating the model based, at least in part, on feedback associated with one or more decoding operations. In an example, the one or more properties are selected from a group of properties comprising: a wordline number associated with the data; a time pool grade associated with the data; a read disturb counter associated with the data; a page type in which the data is stored; and a read level of a memory block in which the data is stored.

Examples also describe a controller for a data storage device, comprising: a property determination system operable to determine one or more properties associated with data identified in a read request received from a host device; a failed bit count (FBC) prediction system operable to predict a FBC of the data while bypassing a read operation that determines a bit error rate (BER) of one or more codewords associated with the data; and a decoder selection system operable to select a particular decoder from a pool of decoders that will decode the one or more codewords associated with the data, wherein the decoder selection system selects the particular decoder based, at least in part, on the FBC of the data. In an example, the decoder selection system is further operable to select a parallelism rate for the particular decoder, wherein the parallelism rate is based, at least in part, on the FBC of the data. In an example, the one or more properties are physical properties of one or more memory blocks in which the data is stored. In an example, the FBC prediction system provides the one or more properties to a model. In an example, the model is trained in an offline environment. In an example, the FBC prediction system is further operable to update the model based, at least in part, on feedback associated with one or more decoding operations. In an example, the one or more properties are selected from a group of properties comprising: a wordline number associated with the data; a time pool grade associated with the data; a read disturb counter associated with the data; a page type in which the data is stored; and a read level of a memory block in which the data is stored.

Still other examples describe a data storage device, comprising: means for receiving a read request from a host device; means for identifying data associated with the read request; means for identifying one or more properties associated with the data; means for predicting a failed bit count (FBC) of the data while bypassing a read operation that determines a bit error rate (BER) of one or more codewords associated with the data, wherein the means for predicting the FBC of the data predicts the FBC of the data based, at least in part, on the one or more properties associated with the data; and means for selecting a particular decoder from a pool of decoders, wherein the means for selecting the particular decoder from the pool of decoders selects the particular decoder based, at least in part, on the FBC of the data. In an example, the data storage device also includes means for providing the one or more codewords associated with the data to the particular decoder. In an example, the data storage device also includes means for determining a parallelism rate for the particular decoder. In an example, the means for determining the parallelism rate for the particular decoder determines the parallelism rate for the particular decoder based, at least in part, on the FBC associated with the data. In an example, the one or more properties are physical properties of one or more memory blocks in which the data is stored. In an example, the means for predicting the FBC of the data is a statistical model

One of ordinary skill in the art will recognize that the technology described herein is not limited to a single specific memory structure, but covers many relevant memory structures within the spirit and scope of the technology as described herein and as understood by one of ordinary skill in the art.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

References to an element herein using a designation such as "first," "second," and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method, comprising:
receiving a command from a host device, the command denoting data to be read from a data storage device;
identifying one or more properties associated with the data;
predicting based, at least in part, on the one or more properties associated with the data, a failed bit count (FBC) of the data while bypassing a read operation that determines a bit error rate (BER) of one or more codewords associated with the data;
identifying a particular decoder from a pool of decoders based, at least in part, on the FBC of the data; and
providing the one or more codewords associated with the data to the particular decoder.

2. The method of claim 1, further comprising determining based, at least in part, on the FBC associated with the data, a parallelism rate for the particular decoder.

3. The method of claim 1, wherein the one or more properties are physical properties of one or more memory blocks in which the data is stored.

4. The method of claim 1, wherein the one or more properties are provided to a model that predicts the FBC of the data.

5. The method of claim 4, wherein the model is trained in an offline environment.

6. The method of claim 4, further comprising updating the model based, at least in part, on feedback associated with one or more decoding operations.

7. The method of claim 1, wherein the one or more properties are selected from a group of properties comprising: a wordline number associated with the data; a time pool grade associated with the data; a read disturb counter associated with the data; a page type in which the data is stored; and a read level of a memory block in which the data is stored.

8. A controller for a data storage device, comprising:
a property determination system operable to determine one or more properties associated with data identified in a read request received from a host device;
a failed bit count (FBC) prediction system operable to predict a FBC of the data while bypassing a read operation that determines a bit error rate (BER) of one or more codewords associated with the data; and
a decoder selection system operable to select a particular decoder from a pool of decoders that will decode the one or more codewords associated with the data, wherein the decoder selection system selects the particular decoder based, at least in part, on the FBC of the data.

9. The controller of claim 8, wherein the decoder selection system is further operable to select a parallelism rate for the particular decoder, wherein the parallelism rate is based, at least in part, on the FBC of the data.

10. The controller of claim 8, wherein the one or more properties are physical properties of one or more memory blocks in which the data is stored.

11. The controller of claim 8, wherein the FBC prediction system provides the one or more properties to a model.

12. The controller of claim 11, wherein the model is trained in an offline environment.

13. The controller of claim 11, wherein the FBC prediction system is further operable to update the model based, at least in part, on feedback associated with one or more decoding operations.

14. The controller of claim 8, wherein the one or more properties are selected from a group of properties comprising: a wordline number associated with the data; a time pool grade associated with the data; a read disturb counter associated with the data; a page type in which the data is stored; and a read level of a memory block in which the data is stored.

15. A data storage device, comprising:
means for receiving a read request from a host device;
means for identifying data associated with the read request;
means for identifying one or more properties associated with the data;
means for predicting a failed bit count (FBC) of the data while bypassing a read operation that determines a bit error rate (BER) of one or more codewords associated with the data, wherein the means for predicting the FBC of the data predicts the FBC of the data based, at least in part, on the one or more properties associated with the data; and
means for selecting a particular decoder from a pool of decoders, wherein the means for selecting the particular decoder from the pool of decoders selects the particular decoder based, at least in part, on the FBC of the data.

16. The data storage device of claim 15, further comprising means for providing the one or more codewords associated with the data to the particular decoder.

17. The data storage device of claim 15, further comprising means for determining a parallelism rate for the particular decoder.

18. The data storage device of claim 17, wherein the means for determining the parallelism rate for the particular decoder determines the parallelism rate for the particular decoder based, at least in part, on the FBC associated with the data.

19. The data storage device of claim 15, wherein the one or more properties are physical properties of one or more memory blocks in which the data is stored.

20. The data storage device of claim 15, wherein the means for predicting the FBC of the data is a statistical model.
